(19) United States
(12) Patent Application Publication
(10) Pub. No.: US 2010/0266961 A1
(43) Pub. Date: Oct. 21, 2010

(54) MOVABLE BODY APPARATUS, EXPOSURE APPARATUS, EXPOSURE METHOD, AND DEVICE MANUFACTURING METHOD

(75) Inventors: Shuji KAWAMURA, Yokohama-shi (JP); Atsushi HARA, Yokohama-shi (JP)

Correspondence Address: OLIFF & BERRIDGE, PLC, P.O. BOX 320850, ALEXANDRIA, VA, 22320-4850, US

(73) Assignee: NIKON CORPORATION, TOKYO (JP)

(21) Appl. No.: 12/764,529

(22) Filed: Apr. 21, 2010

Related U.S. Application Data
(60) Provisional application No. 61/213,027, filed on Apr. 29, 2009.

(30) Foreign Application Priority Data
Apr. 21, 2009 (JP) 2009-102714

(51) Int. Cl. G03B 27/42; G03F 7/20

(52) U.S. Cl. 430/319; 355/53; 430/325

(57) ABSTRACT

In a substrate stage device, when an X coarse movement stage moves in an X-axis direction, a Y coarse movement stage, an empty-weight cancelling device and a Y beam move integrally with the X coarse movement stage, and when the Y coarse movement stage moves in a Y-axis direction on the X-coarse movement stage, the empty-weight cancelling device moves integrally with the Y coarse movement stage in the Y-axis direction on the Y beam. Since the Y beam is arranged extending in the Y-axis direction in a state of covering a movement range of the empty-weight cancelling device in the Y-axis direction, the empty-weight cancelling device is constantly supported by the Y beam regardless of the position of the empty-weight cancelling device. Accordingly, a substrate can be guided along an XY plane with high accuracy, without providing a member (e.g. a surface plate or the like) having a guide surface that is large enough to cover the entire movement range of the empty-weight cancelling device.

### CROSS-REFERENCE TO RELATED APPLICATIONS

This non-provisional application claims the benefit of Provisional Application No. 61/213,027 filed Apr. 29, 2009, the disclosure of which is hereby incorporated herein by reference in its entirety.

### BACKGROUND OF THE INVENTION

1. Field of the Invention

The present invention relates to movable body apparatuses, exposure apparatuses, exposure methods and device manufacturing methods, and more particularly to a movable body apparatus equipped with a movable body that moves along a predetermined two-dimensional plane, an exposure apparatus equipped with the movable body apparatus, an exposure method of exposing an object by irradiating the object with an energy beam, and a device manufacturing method that uses the exposure apparatus or the exposure method.

2. Description of the Background Art

Conventionally, in a lithography process for manufacturing electron devices (microdevices) such as liquid crystal display elements or semiconductor devices (integrated circuits or the like), an exposure apparatus such as a projection exposure apparatus by a step-and-repeat method (a so-called stepper), or a projection exposure apparatus by a step-and-scan method (a so-called scanning stepper, which is also called a scanner) is used.

In recent years, however, a substrate that is subject to exposure in an exposure apparatus (especially, a glass plate that is subject to exposure in a liquid crystal exposure apparatus) has tended to increasingly grow in size, and in the exposure apparatus as well, a size of a substrate table that holds the substrate has increased, and position control of the substrate becomes difficult owing to the weight increase accompanying the size increase. As the solution to solve such a problem, an exposure apparatus has been developed in which the empty weight of a substrate table is supported with an empty-weight cancelling device (empty-weight canceller) made up of a columnar member (e.g., refer to PCT International Publication No. 2008/129762 and the corresponding U.S. Patent Application Publication No. 2010/0018950, and the like).

In this type of the exposure apparatus, the empty-weight cancelling device moves integrally with the substrate table along the upper surface (guide surface) of a surface plate that is formed by, for example, stone.

However, in order to drive a substrate, which has grown in size, with a long stroke along a two-dimensional plane parallel to a horizontal plane, it is necessary to increase the size of the surface plate having the guide surface used when the empty-weight cancelling device moves, and therefore, the machining, the transportation and the like of the surface plate become difficult.

Further, in the exposure apparatus described in PCT International Publication No. 2008/129762, in order to integrally move the empty-weight cancelling device and the substrate table along the two-dimensional plane, the empty-weight cancelling device and a part of a stage device that includes the substrate table are mechanically coupled. Therefore, the measures to restrain vibration from being transmitted from the outside via the stage device needs to be taken with respect to the empty-weight cancelling device.

### SUMMARY OF THE INVENTION

According to a first aspect of the present invention, there is provided a first movable body apparatus, comprising: a first movable body that is movable along a two-dimensional plane that includes a first axis and a second axis orthogonal to each other; an empty-weight supporting member that supports an empty weight of the first movable body, and moves along a plane parallel to the two-dimensional plane integrally with the first movable body within a predetermined range; and a movable support member arranged extending in a direction parallel to the first axis at least within the predetermined range, which supports the empty-weight supporting member and moves integrally with the empty-weight supporting member in a direction parallel to the second axis.

With this apparatus, since the movable support member is arranged extending in the direction parallel to the first axis, the movable support member can support the empty-weight supporting member even if the empty-weight supporting member moves in the direction parallel to the first axis. Further, when the empty-weight supporting member moves in the direction parallel to the second axis, the movable support member moves integrally with the empty-weight supporting member in the direction parallel to the second axis, and therefore, the movable support member can support the empty-weight supporting member even in the case when the empty-weight supporting member moves in the direction parallel to the second axis (which also includes the case when such movement is accompanied by movement in the direction parallel to the first axis). Accordingly, a member (e.g. a surface plate) having a guide surface that is large enough to cover a movement range of the empty-weight supporting member so as to support the empty-weight supporting member does not have to be provided.

According to a second aspect of the present invention, there is provided a second movable body apparatus, comprising: a first movable body that is movable along a two-dimensional plane that includes a first axis and a second axis orthogonal to each other; a second movable body that supports the first movable body, and drives the first movable body along a plane parallel to the two-dimensional plane by moving along a plane parallel to the two-dimensional plane within a predetermined range; an empty-weight supporting member that supports an empty weight of the first movable body, and moves along a plane parallel to the two-dimensional plane integrally with the second movable body; and a static gas bearing that blows out a gas to between the second movable body and the empty-weight supporting member, wherein the second movable body presses the empty-weight supporting member in a noncontact manner via the gas blown out from the static gas bearing when the second movable body moves along the plane parallel to the two-dimensional plane.

With this apparatus, the empty-weight supporting member moves along the plane parallel to the two-dimensional plane integrally with the second movable body by being pressed by the second movable body via the gas blown out from the static gas bearing. Accordingly, vibration from the second movable body or the like (disturbance) does not travel to the empty-weight supporting member and the empty-weight supporting member can stably support the first movable body.

According to a third aspect of the present invention, there is provided a first exposure apparatus to expose an object by irradiating the object with an energy beam, the apparatus comprising: one of the first and second movable body apparatuses of the present invention in which the object is held by the first movable body; and a patterning device that irradiates the object mounted on the first movable body with the energy beam.

According to a fourth aspect of the present invention, there is provided a device manufacturing method, comprising: exposing an object using the first exposure apparatus of the present invention; and developing the object that has been exposed.

According to a fifth aspect of the present invention, there is provided a first exposure method of exposing an object by irradiating the object with an energy beam, the method comprising: driving a first movable body that holds the object, along a two-dimensional plane that includes a first axis and a second axis orthogonal to each other, within a predetermined range in the two-dimensional plane; causing an empty-weight supporting member to move along a plane parallel to the two-dimensional plane integrally with the first movable body, the empty-weight supporting member supporting an empty weight of the first movable body; driving a movable support member integrally with the empty-weight supporting member in a direction parallel to the second axis, the movable support member being arranged extending in a direction parallel to the first axis at least within the predetermined range and supporting the empty-weight supporting member; and irradiating the object with the energy beam.

With this method, since the movable support member is arranged extending in the direction parallel to the first axis, the movable support member can support the empty-weight supporting member even if the empty-weight supporting member moves in the direction parallel to the first axis. Further, when the empty-weight supporting member moves in the direction parallel to the second axis, the movable support member moves integrally with, the empty-weight supporting member in the direction parallel to the second axis, and therefore, the movable support member can support the empty-weight supporting member even in the case when the empty-weight supporting member moves in the direction parallel to the second axis (which also includes the case when such movement is accompanied by movement in the direction parallel to the first axis). Accordingly, a member (e.g. a surface plate) having a guide surface that is large enough to cover a movement range of the empty-weight supporting member so as to support the empty-weight supporting member does not have to be provided.

According to a sixth aspect of the present invention, there is provided a second exposure method of exposing an object by irradiating the object with an energy beam, the method comprising: driving a first movable body that holds the object along a plane parallel to a predetermined two-dimensional plane using a second movable body that is movable along a plane parallel to the two-dimensional plane; causing an empty-weight supporting member that supports an empty weight of the first movable body to move along a plane parallel to the two-dimensional plane integrally with the second movable body; causing the second movable body to press the empty-weight supporting member in a noncantact manner via a gas blown out from a static gas bearing to between the second movable body and the empty-weight supporting member, when the second movable body moves along the plane parallel to the two-dimensional plane; and irradiating the object with the energy beam.

With this method, the empty-weight supporting member moves along the plane parallel to the two-dimensional plane integrally with the second movable body by being pressed by the second movable body via the gas blown out from the static gas bearing. Accordingly, vibration from the second movable body or the like (disturbance) does not travel to the empty-weight supporting member and the empty-weight supporting member can stably support the first movable body.

According to a seventh aspect of the present invention, there is provided a device manufacturing method, comprising: exposing an object using one of the first and second exposure methods of the present invention; and developing the object that has been exposed.

According to an eighth aspect of the present invention, there is provided a second exposure apparatus to expose an object by irradiating the object with an energy beam, the apparatus comprising: a first stage that is movable along a two-dimensional plane that includes a first axis and a second axis orthogonal to each other, while holding the object; an empty-weight supporting member that supports an empty weight of the first stage, and moves along a plane parallel to the two-dimensional plane integrally with the first stage within a predetermined range; a movable support member arranged extending in a direction parallel to the first axis at least within the predetermined range, which supports the empty-weight supporting member and moves integrally with the empty-weight supporting member in a direction parallel to the second axis; and a patterning device that irradiates the object held by the first stage with the energy beam.

With this apparatus, since the movable support member is arranged extending in the direction parallel to the first axis, the movable support member can support the empty-weight supporting member even if the empty-weight supporting member moves in the direction parallel to the first axis. Further, when the empty-weight supporting member moves in the direction parallel to the second axis, the movable support member moves integrally with the empty-weight supporting member in the direction parallel to the second axis, and therefore, the movable support member can support the empty-weight supporting member even in the case when the empty-weight supporting member moves in the direction parallel to the second axis (which also includes the case when such movement is accompanied by movement in the direction parallel to the first axis). Accordingly, a member (e.g. a surface plate) having a guide surface that is large enough to cover a movement range of the empty-weight supporting member so as to support the empty-weight supporting member does not have to be provided.

According to a ninth aspect of the present invention, there is provided a third exposure apparatus to expose an object by irradiating the object with an energy beam, the apparatus comprising: a first stage that is movable along a two-dimensional plane that includes a first axis and a second axis orthogonal to each other, while holding the object; a second stage that supports the first stage, and drives the first stage along a plane parallel to the two-dimensional plane by moving along a plane parallel to the two-dimensional plane within a predetermined range; an empty-weight supporting member that supports an empty weight of the first stage, and moves along a plane parallel to the two-dimensional plane integrally with the second stage; a static gas bearing that blows out a gas to between the second stage and the empty-weight supporting member; and a patterning device that irradiates the object held by the first stage with the energy beam, wherein the second stage presses the empty-weight supporting member in a noncontact manner via the gas blown out from the static gas bearing, when the second stage moves along the plane parallel to the two-dimensional plane.

With this apparatus, the empty-weight supporting member moves along the plane parallel to the two-dimensional plane integrally with the second stage by being pressed by the second stage via the gas blown out from the static gas bearing. Accordingly, vibration from the second stage or the like (disturbance) does not travel to the empty-weight supporting member and the empty-weight supporting member can stably support the first stage.

According to a tenth aspect of the present invention, there is provided a device manufacturing method, comprising: exposing a substrate using any one of the first to third exposure apparatuses of the present invention; and developing the substrate that has been exposed.

In this case, there is provided a manufacturing method of manufacturing a flat-panel display as a device by using, as the substrate, a substrate for a flat-panel display. The substrate for a flat-panel display includes a film-like member or the like, besides a glass substrate or the like.

### BRIEF DESCRIPTION OF THE DRAWINGS

In the accompanying drawings;

FIG. 1 is a view showing a schematic configuration of a liquid crystal exposure apparatus of an embodiment;

FIG. 2 is a perspective view showing a stage device which the exposure apparatus of FIG. 1 has, with partial omission;

FIG. 3 is a side view (partial cross sectional view) of the stage when viewed from a Y-axis direction;

FIG. 4 is a side view (partial cross sectional view) of the stage when viewed from an X-axis direction;

FIG. 5 is a view showing a coupling structure between an empty-weight cancelling device and a Y coarse movement stage; and

FIG. 6 is a view showing a coupling structure between a Y beam and an X coarse movement stage.

### DESCRIPTION OF THE EMBODIMENTS

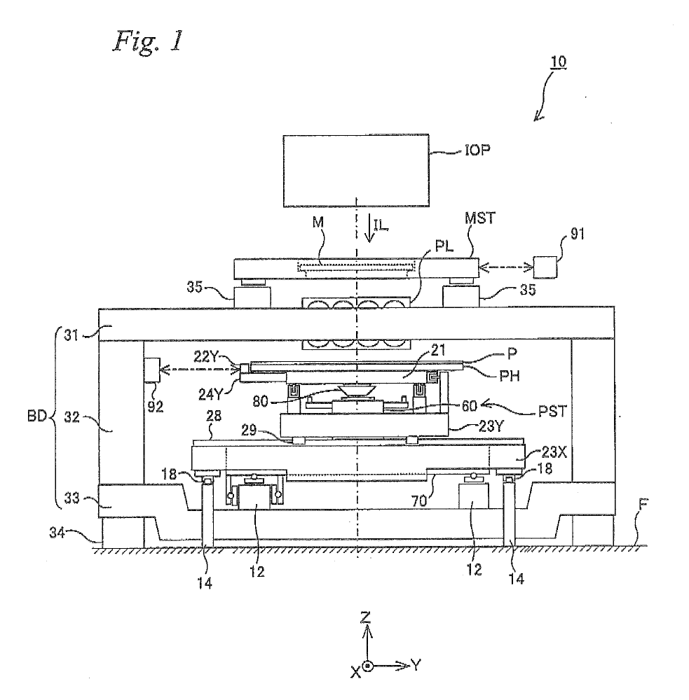

An embodiment of the present invention is described below, with reference to FIGS. 1 to 6.

FIG. 1 shows a schematic configuration of a liquid crystal exposure apparatus 10 related to the embodiment. Liquid crystal exposure apparatus 10 is a projection exposure apparatus by a step-and-scan method, i.e., a so-called scanner.

As shown in FIG. 1, liquid crystal exposure apparatus 10 is equipped with an illumination system 10P, a mask stage MST that holds a mask M, a projection optical system PL, a body BD on which mask stage MST, projection optical system PL and the like are mounted, a substrate stage device PST that includes a fine movement stage 21 that holds a substrate P such that substrate P is movable along an XY plane, and their control system and the like. In the description below, the explanation is given assuming that a direction in which mask M and substrate P are scanned relative to projection optical system PL, respectively, during exposure is an X-axis direction, a direction orthogonal to the X-axis direction within a horizontal plane (the XY plane) is a Y-axis direction, and a direction orthogonal to the X-axis and Y-axis directions is a Z-axis direction, and rotational (tilt) directions around the X-axis, Y-axis and Z-axis are θx, θy and θz directions, respectively.

Illumination system IOP is configured similar to the illumination system that is disclosed in, for example, U.S. Pat. No. 6,552,775 and the like. More specifically, illumination system IOP irradiates mask M with a light emitted from a mercury lamp (not illustrated), as an illumination light for exposure (illumination light) IL, via a reflection mirror, a dichroic mirror, a shutter, a wavelength selecting filter, various types of lenses and the like, which are not illustrated. As illumination light IL, for example, a light such as an i-line (with a wavelength of 365 nm), a g-line (with a wavelength of 436 nm) or an h-line (with a wavelength of 405 nm) (or a synthetic light of the i-line, the g-line and the h-line described above) is used. Further, the wavelength of illumination light IL can be appropriately switched by the wavelength selecting filter according to the required resolution. Incidentally, the light source is not limited to an ultrahigh pressure mercury lamp, but for example, a pulsed laser light source such as an excimer laser, or a solid state laser device or the like can also be used.

On mask stage MST, mask M having a pattern surface (the lower surface in FIG. 1) on which a circuit pattern and the like are formed is fixed by, for example, vacuum adsorption. Mask stage MST is supported in a noncontact manner via, for example, air bearings (air pads) that are not illustrated, above a pair of mask stage guides 35 with the X-axis direction serving as their longitudinal directions that are integrally fixed to the upper surface of a barrel surface plate 31 that is a part of body BD that is described later on. Mask stage MST is driven in a scanning direction (the X-axis direction) with a predetermined stroke and also is finely driven in the Y-axis direction and the θz direction, above the pair of mask stage guides 35, by a mask stage driving system (not illustrated) that includes, for example, a liner motor.

Positional information (including rotational information in the θz direction) of mask stage MST within the XY plane is constantly measured at a resolution of, for example, around 0.5 to 1 nm with a mask laser interferometer (hereinafter, referred to as a “mask interferometer”) 91, via a reflection surface fixed (or formed) on mask stage MST. The measurement values of mask interferometer 91 are sent to a main controller (the illustration is omitted) that performs the overall control of the respective elements constituting liquid crystal exposure apparatus 10, and the main controller controls the position (and the speed) of mask stage MST in the X-axis direction, the Y-axis direction and the θz direction via the mask stage driving system, based on the measurement values of mask interferometer 91.

Projection optical system PL is supported below mask stage MST in FIG. 1, by barrel surface plate 31. Projection optical system PL in the embodiment has a configuration similar to the projection optical system disclosed in, for example, U.S. Pat. No. 6,552,775. More specifically, projection optical system PL includes a plurality of projection optical systems (multi-lens projection optical systems) whose projection areas, where a pattern image of mask M is projected, are placed in a zigzag shape, and functions equivalently to a projection optical system that has a single image field with a rectangular shape whose longitudinal direction is in the Y-axis direction. In the embodiment, as each of the plurality of projection optical systems, for example, a projection optical system that is a both-side telecentric equal-magnification system that forms an erected normal image is used. In the description below, the plurality of projection areas placed in a zigzag shape of projection optical system PL are also referred to as an exposure area as a whole.

Therefore, when an illumination area on mask M is illuminated with illumination light IL from illumination system IOP, by illumination light IL that has passed through mask M whose pattern surface is placed substantially coincident with the first plane (object plane) of projection optical system PL, a projected image (partial erected image) of a circuit pattern of mask M within the illumination area is formed on an irradiation area (exposure area) of illumination light IL that is conjugate to the illumination area, on substrate P which is placed on the second plane (image plane) side of projection optical system PL and whose surface is coated with a resist (sensitive agent), via projection optical system PL. Then, by moving mask M relative to the illumination area (illumination light IL) in the scanning direction (X-axis direction) and also moving substrate P relative to the exposure area (illumination light IL) in the scanning direction (X-axis direction) by synchronous drive of mask stage MST and fine movement stage 21, scanning exposure of one shot area (divided area) on substrate P is performed, and a pattern of mask M is transferred onto the shot area. More specifically, in the embodiment, a pattern of mask M is generated on substrate P by illumination system IOP and projection optical system PL, and the pattern is formed on substrate P by exposure of a sensitive layer (resist layer) on substrate P with illumination light IL.

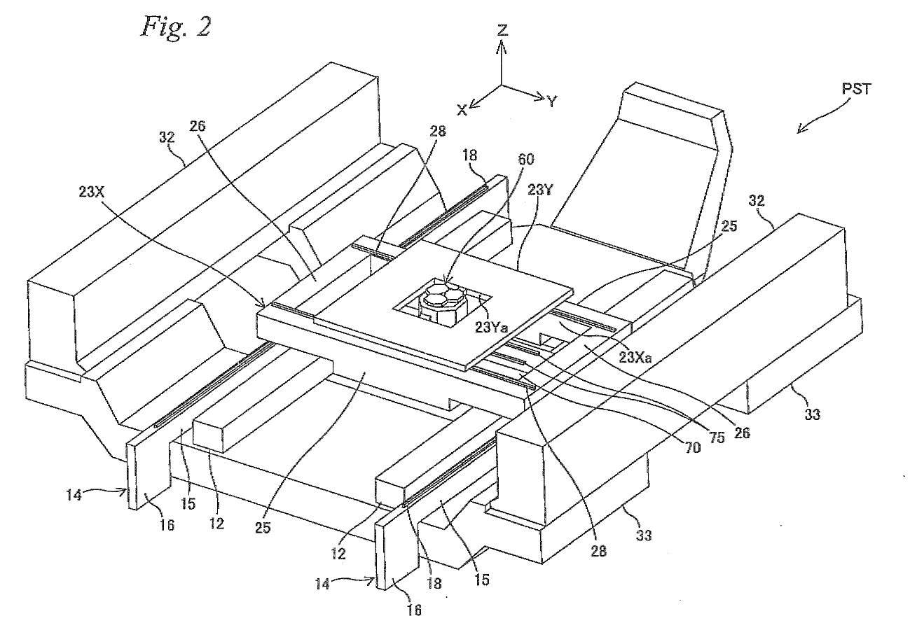

As disclosed in, for example, U.S. Patent Application Publication No. 2008/0030702 and the like, body BD has substrate stage mountings 33 and barrel surface plate 31 that is horizontally supported via support members 32 placed on substrate stage mountings 33. As can be seen from FIGS. 1 and 2, substrate stage mountings 33 are each made up of a member whose longitudinal direction is in the Y-axis direction, and two (a pair) of substrate stage mountings 33 are placed at a predetermined distance in the X-axis direction. Each of the two substrate stage mountings 33 has both ends in the longitudinal direction that are severally supported by a vibration isolating mechanism 34 (see FIG. 1) installed on a floor surface F, and is separate from floor surface F vibrationwise.

As shown in FIG. 1, substrate stage device PST is equipped with a plurality (e.g, a pair, in the embodiment) of base frames 14 placed on floor surface F, a pair of X guides 12 fixed on substrate stage mountings 33, an X coarse movement stage 23X that is driven in the X-axis direction on a plurality of base frames 14, a Y coarse movement stage 23Y that is driven in the Y-axis direction on X coarse movement stage 23X and configures, together with X coarse movement stage 23X, an XY two-dimensional stage device, a fine movement stage 21 placed on the +Z side of (above) Y coarse movement stage 23Y, an empty-weight cancelling device 60 that moves within the XY plane in conjunction with fine movement stage 21, a leveling device 80 placed between empty-weight cancelling device 60 and fine movement stage 21, and a Y beam 70 that is a stringer-like member installed over the pair of X guides 12 and supports empty-weight cancelling device 60.

As shown in FIG. 2, the pair of base frames 14 are placed at a predetermined distance in the Y-axis direction. Each of the pair of base frames 14 has a guide section 15 that is arranged extending in the X-axis direction on the two (the pair of) substrate stage mountings 33, and a plurality, e.g., three of leg sections 16 (the illustration of the leg sections in the center and on the −X side is omitted in FIG. 2) that support both ends and the center portion of guide section 15 in the longitudinal direction, on floor surface F (see FIG. 1). On the upper surface of each of a pair of guide sections 15, an X guide 18 arranged extending in the X-axis direction is fixed. Base frames 14 and substrate stage mountings 33 are mechanically non-connected (noncontact) and are separate vibrationwise, and therefore, for example, vibration (disturbance) from the floor is restrained from being transmitted from base frames 14 to substrate stage mountings 33.

Each of the pair of X guides 12 is a columnar (bar-like) member having a rectangular sectional shape that is formed by, for example, stone and has its longitudinal direction in the X-axis direction, and X guides 12 are placed on the inner side of the pair of base frames 14, in a state of being installed over the two substrate stage mountings 33. The upper surface of each of the pair of X guides 12 is made to be parallel to the XY plane and is finished so as to have a very high flatness degree.

As shown in FIG. 2, X coarse movement stage 23X is equipped with Y beam members 25 that are a pair of members placed at a predetermined distance in the X-axis direction with the Y-axis direction serving as their longitudinal directions and a pair of connecting members 26 that respectively connect both ends of a pair of Y beam members 25 in the longitudinal direction, and X coarse movement stage 23X is formed so as to have a rectangular frame shape in a planar view and has an opening section 23Xa in the center portion that penetrates in the Z-axis direction.

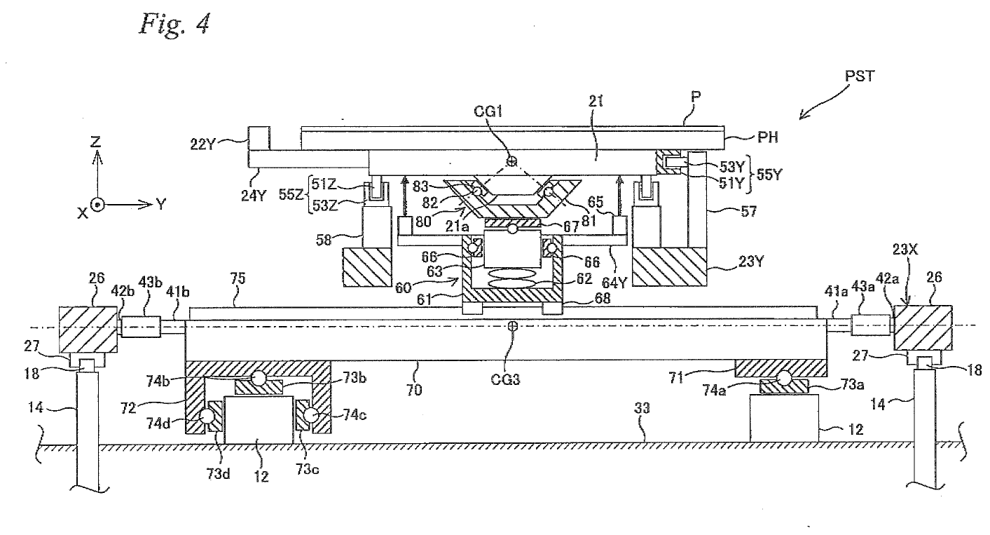

As shown in FIG. 2, the pair of connecting members 26 are supported by the pair of base frames 14, respectively. As shown in FIG. 4, on the lower surface of each of the pair of connecting members 26, a slide section 27 having an inverse U-like sectional shape is fixed that includes a plurality of rolling bearings (e.g. balls, or skids), which are not illustrated, and mechanically engages with X guide 18 fixed to the upper surface of base frame 14, in a slidable state with respect to X guide 18. Further, as shown in FIG. 2, on the upper surface of each of the pair of Y beam members 25, a Y guide 28 arranged extending in the Y-axis direction is fixed. Further, although the illustration is omitted in the respective drawings, guide section 15 of each of the pair of base frames 14 has, for example, a magnetic unit that includes a plurality of magnets disposed at a predetermined distance in the x-axis direction, and on the lower surface of each of the pair of connecting members 26 of X coarse movement stage 23X, a coil unit including a plurality of coils is fixed so as to be opposed to the magnetic unit. The magnetic units of base frames 14 and the coil units of X coarse movement stage 23X configure an X linear motor by the Lorentz force drive method that drives X coarse movement stage 23X in the X-axis direction.

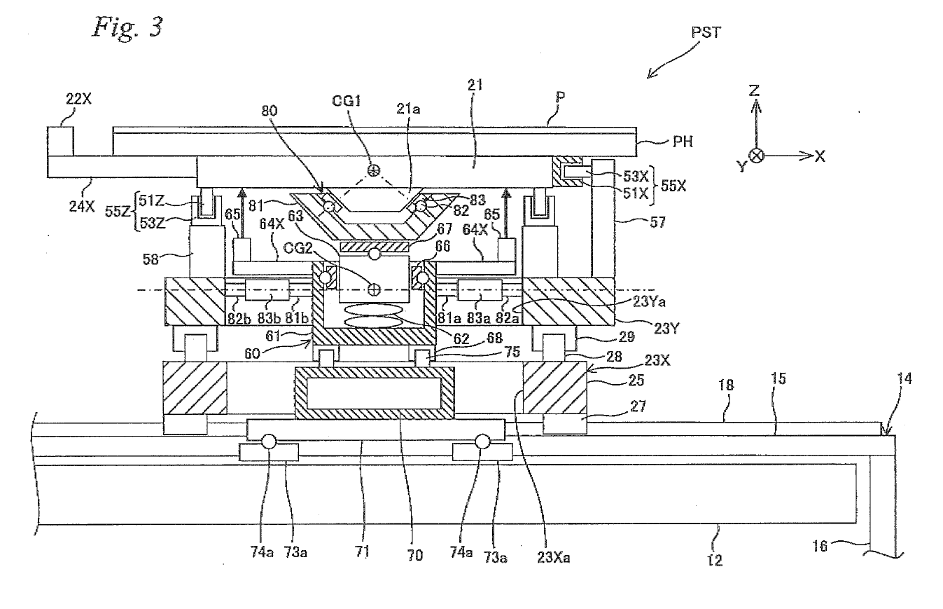

As shown in FIG. 2, Y coarse movement stage 23Y is made up of a plate-shaped (or a rectangular parallelepiped shape) member having a roughly square shape in a planar view, and has an opening section 23Ya in the center portion that penetrates in the Z-axis direction. Further, as can be seen from FIGS. 1 and 3, at four corner portions on the lower surface of Y coarse movement stage 23Y, a slide section 29 having an inverse U-like sectional shape is respectively fixed that includes a plurality of rolling bearings that are not illustrated, and mechanically engages on each of a pair of Y guides 28 that are respectively fixed to the pair of Y beam members 25 described earlier, in a slidable state with respect to Y guide 28. Incidentally, although the illustration is omitted in the respective drawings, on the upper surface of each of the pair of Y beam members 25, for example, a magnetic unit that includes a plurality of magnets disposed at a predetermined distance in the Y-axis direction is fixed parallel to Y guides 28, and on the ends on the +X side and the −X side of the lower surface of Y coarse movement stage 23Y, a coil unit including a plurality of coils is fixed so as to be opposed to the magnetic unit on Y beam member 25. The magnetic units of Y beam members 25 and the coil units of Y coarse movements stage 23Y configure a Y linear motor by the Lorentz force drive method that drives Y coarse movement stage 23Y in the Y-axis direction on X coarse movement stage 23X. Incidentally, the drive method (actuator) of the X coarse movement stage and the Y coarse movement stage is not limited thereto but can be a ball screw drive, a belt drive or the like.

As shown in FIG. 3, on the end on the +X side of the upper surface of Y coarse movement stage 23Y, a plurality, e.g., three of X stators 53X placed at a predetermined distance in the Y-axis direction (overlapping in the depth direction of the drawing of FIG. 3) are fixed via a columnar support member 57 arranged extending in the Z-axis direction. Further, as shown in FIG. 4, on the end on the +Y side of the upper surface of Y coarse movement stage 23Y, a plurality, e.g., three of Y stators 53Y placed at a predetermined distance in the X-axis direction (overlapping in the depth direction of the drawing of FIG. 4) are fixed via columnar support member 57 arranged extending in the Z-axis direction. X stators 53X and Y stators 53Y each have a coil unit including a plurality of coils (the illustration is omitted).

Further, as can be seen from FIGS. 3 and 4, at four corner portions on the upper surface of Y coarse movement stage 23Y (in this case, inwardly from support members 57 that support X stators 53X and Y stators 53Y respectively), a Z stator 53Z having a U-like sectional shape is fixed via a support member 58 (however, the illustration of the Z stator on the +X side and the −Y side is omitted). Z stators 53Z each have a magnetic unit including a plurality of magnets (the illustration is omitted) on a pair of opposed surfaces that are opposed to each other.

As shown in FIGS. 3 and 4, fine movement stage 21 is made up of a plate-shaped (or a rectangular parallelepiped-shaped) member having a roughly square shape in a planar view, and has a substrate holder PH on its upper surface. Substrate holder PH has, for example, at least a part of a vacuum adsorption mechanism (or an electrostatic adsorption mechanism) that is not illustrated, and holds substrate P by adsorption on its upper surface.

As shown in FIGS. 3 and 4, on the side surface on the −X side and on the side surface on the −Y side of fine movement stage 21, movable mirrors (bar mirrors) 22X and 22Y are fixed via fixed members 24X and 24Y, respectively. The surface on the −X side of movable mirror 22X and the surface of the −Y side of movable mirror 22Y are respectively mirror-finished to serve as the reflection surfaces. Positional information of fine movement stage 21 within the XY plane is constantly measured at a resolution of, for example, around 0.5 to 1 nm, with a laser interferometer system 92 (see FIG. 1) that irradiates movable mirrors 22X and 22Y with measurement beams. Incidentally, while laser interferometer system 92 is actually equipped with an X laser interferometer and a Y laser interferometer that correspond to X movable mirror 22X and movable mirror 221 respectively, only the Y laser interferometer is representatively illustrated in FIG. 1.

Further, as shown in FIG. 3, on the side surface on the +X side of fine movement stage 21, a plurality, e.g., three of X movers 51X each having a U-like sectional shape placed at a predetermined distance in the Y-axis direction are fixed. Further, as shown in FIG. 4, on the side surface on the +Y side of fine movement stage 21, a plurality, e.g., three of Y movers 51Y each having a U-like sectional shape placed at a predetermined distance in the X-axis direction are fixed. Each of X movers 51X and Y movers 51Y has a magnetic unit including a plurality of magnets (the illustration is omitted) on a pair of opposed surfaces that are opposed to each other. The three Y movers 51Y configure, together with the three Y stators 53Y, three voice coil motors 55Y for Y-axis direction drive (hereinafter, shortly referred to as Y-axis VCMs 55Y) by the Lorentz force drive method, respectively, and the three X movers 51X configure, together with the three X stators 53X, three voice coil motors 55X for X-axis direction drive (hereinafter, shortly referred to as X-axis VCMs 55X) by the Lorentz force drive method, respectively. The main controller (the illustration is omitted) that perform the overall control of the respective elements constituting liquid crystal exposure apparatus 10 drives fine movement stage 21 in the θz direction, by, for example, making drive forces (thrusts) generated by X-axis VCMs 55X (or Y-axis VCMs 55Y) on both ends, from among the three X-axis VCMs 55X (or the three Y-axis VCMs 55Y), to be different.

Further, as can be seen from FIGS. 3 and 4, at four corner portions on the lower surface of fine movement stage 21, a Z mover 51Z is fixed (however, the illustration of the Z mover on the +X side and the −Y side is omitted). Z movers 51Z each have a coil unit including a plurality of coils (the illustration is omitted) The four Z movers 51Z configure, together with the four Z stators 53Z, four voice coil motors 55Z for Z-axis direction drive (hereinafter, shortly referred to as Z-axis VCMs 55Z) by the Lorentz force drive method, respectively. The main controller, which is not illustrated, drives (vertically moves) fine movement stage 21 in the Z-axis direction by controlling the respective thrusts of the four Z-axis VCMs 55Z to be the same. Further, the main controller drives fine movement stage 21 in the θx direction and the θy direction by controlling the thrusts of the respective Z-axis VCMs 55Z to be different. Incidentally, while the four Z-axis VCMs 55Z are placed so as to correspond to the four corner portions of the fine movement stage in the embodiment, this is not intended to be limiting, and the Z-axis VCM 55Z can be placed at three positions so as to generate the thrusts in the Z-axis direction from at least three non-collinear points.

With the configuration as described above, in substrate stage device PST, fine movement stage 21 (i.e. substrate P) is movable (coarsely movable) with a long stroke in the two axes e. X-axis and Y-axis) directions, and also is movable (finely movable) with a minute stroke in directions of six degrees of freedom (the X-axis, Y-axis and Z-axis directions and the θx, θy and θz directions). Incidentally, in the embodiment, while the X-axis VCMs and the Y-axis VCMs are each the voice coil motor by a moving magnet type in which the mover has the magnetic unit, this is not intended to be limiting, and for example, the X-axis VCMs and the Y-axis VCMs can each be a voice coil motor by a moving coil type in which a mover has a coil unit. Further, while the Z-axis VCMs in the embodiment are each the voice coil motor by a moving coil type in which the mover has the coil unit, this is not intended to be limiting, and for example, the Z-axis VCMs can each be a voice coil motor by a moving magnet type in which a mover has a magnetic unit. Further, the drive method can be a drive method other than the Lorentz force drive method. Similarly, each of the linear motors such as the X-linear motor and the Y-linear motor described above, which exposure apparatus 10 is equipped with, can be of either the moving magnet type or the moving coil type, and the drive method of each of the linear motors is not limited to the Lorentz force drive method, but can be another drive method such as a variable magnetoresistance drive method.

Empty-weight cancelling device 60 (which is also referred to as a central pillar) is a member that supports the empty weight of a system including at least fine movement stage 21 (to be more specific, a system composed of fine movement stage 21, substrate holder PH, movable mirrors 22X and 22Y, fixed members 24X and 24Y, and the like, in the embodiment), and is made up of a columnar member arranged extending in the Z-axis direction, and as shown in FIG. 2, is inserted in opening section 23Ya formed in Y coarse movement stage 23Y. Empty-weight cancelling device 60 has a housing 61, an air spring 62 and a slide section 63, as shown in FIGS. 3 and 4.

Housing 61 is made up of a cylinder-like member having a bottom whose +Z side is opened. As can be seen from FIGS. 3 and 4, two (a pair of) X arm members 64X extending in the, +X direction and the −X direction respectively and two (a pair of) Y arm members 64Y extending in the +Y direction and the −Y direction respectively are fixed to the outer side of the upper end of the peripheral wall of housing 61 (hereinafter the four arm members are generically referred to as arm members 64). At the tip of each of the four arm members 64, a probe section 65 is fixed. Meanwhile, on the lower surface of fine movement stage 21, a target section, which is not illustrated, placed so as to correspond to each of the four probe sections 65 described above. Probe sections 65 configure, together with the target sections, capacitance sensors (hereinafter, referred to as Z sensors) that measure a distance between probe sections 65 and the target sections, i.e., the Z-position of fine movement stage 21. The outputs of the Z sensors are supplied to the main controller that is not illustrated. The main controller controls the position of fine movement stage 21 in the Z-axis direction and the tilt quantity of fine movement stage 21 in the θx direction and the θy direction, using the measurement results of the four Z sensors. Incidentally, the number of the Z sensors is not limited to four but can be, for example, three as far as the Z-position of the fine movement stage can be measured in at least three non-collinear positions. Further, the Z sensor is not limited to the capacitance sensor but can be a laser displacement gauge by a CCD method or the like. Further, the positional relation between the probe sections and the target sections that constitute the Z sensors can be opposite to the above-described positional relation.

Air spring 62 is housed in the lowermost section within housing 61. A gas (e.g, air) is supplied from a gas supplying device, which is not illustrated, to air spring 62, which causes the inside of air spring 62 to be set to a positive pressure space whose atmospheric pressure is higher compared with the outside. Empty-weight cancelling device 60 reduces the burden on Z-axis VCMs 55Z by air spring 62 absorbing (cancelling) the empty weight of fine movement stage 21, in a state of supporting fine movement stage 21. Further, air spring 62 also functions as a Z-axis air actuator that drives fine movement stage 21 (i.e. substrate P) in the Z-axis direction with a long stroke by the change of its inner pressure. Instead of air spring 62, a damper also serving as an actuator (e.g. a shock absorber corresponds thereto) that can absorb (cancel) the empty weight of fine movement stage 21 in a state of supporting fine movement stage 21 and can also drive fine movement stage 21 in the Z-axis direction can be used. In this case, a spring by another method such as a bellows method or a hydraulic method can be used.

Slide section 63 is a cylinder-like member housed inside housing 61. On the inner side of the peripheral wall of housing 61, a plurality of air bearing 66 are attached and form a guide used when slide section 63 moves in the Z-axis direction. An air bearing 67 (which is also referred to as a ceiling pad) whose bearing surface faces the +Z direction is attached on the upper surface of slide section 63, and supports a leveling device 80 by levitation.

Leveling device 80 is a member that supports a support subject (a system made up of fine movement stage 21, substrate holder PH, movable mirrors 22X and 22Y, fixed members 24X and 24Y and the like), supported by empty-weight cancelling device 60, such that the support subject can be tilted in the θx and θy directions with a gravity center position CG1 of the support subject serving as the center, and as shown in FIGS. 3 and 4, leveling device 80 is placed between air bearing 67 and a polyhedral member 21a fixed to the lower surface of fine movement stage 21. Leveling device 80 has a leveling cup 81 having a flat bottom surface that is formed into a cup shape, and a plurality, e.g., three of air bearings 83 attached to the inner side surface of leveling cup 81 via ball joints 82. Polyhedral member 21a has an outer shape having side surface sections that are opposed to the bearing surfaces of the three air bearings 83 respectively, or more specifically, an outer shape like a triangular pyramid member whose tip is flatten, and the bottom surface of polyhedral member 21a is integrally fixed to the lower surface of fine movement stage 21.

Leveling cup 81 is supported in a noncontact manner above slide section 63 by the static pressure of a gas blown out from air bearing 67, for example, a high-pressure gas. Further, each of a plurality of air bearings 83 is capable of blowing out a high-pressure gas, for example, air, supplied from a gas supplying device that is not illustrated, to each of the side surfaces (tilted surfaces) of polyhedral member 21a. Therefore, polyhedral member 21a (i.e. a system composed of fine movement stage 21 and the like) is supported in a noncontact manner above by leveling cup 81 in a state where a predetermined clearance is formed between polyhedral member 21a and each air bearing 83, owing to the static pressure of the gas blown out from each air bearing 83. Further, since each air bearing 83 is attached to leveling cup 81 via ball joint 82, fine movement stage 21 is capable of freely oscillating (tilting) in the θx and θy directions in a state where the above-described clearance is maintained. Incidentally, the detailed configurations of empty-weight cancelling device 60, the Z sensors, leveling device 80 and the like are disclosed in, for example, PCT International Publication No. 2008/129762 (the corresponding U.S. Patent Application Publication No. 2010/0018950) and the like.

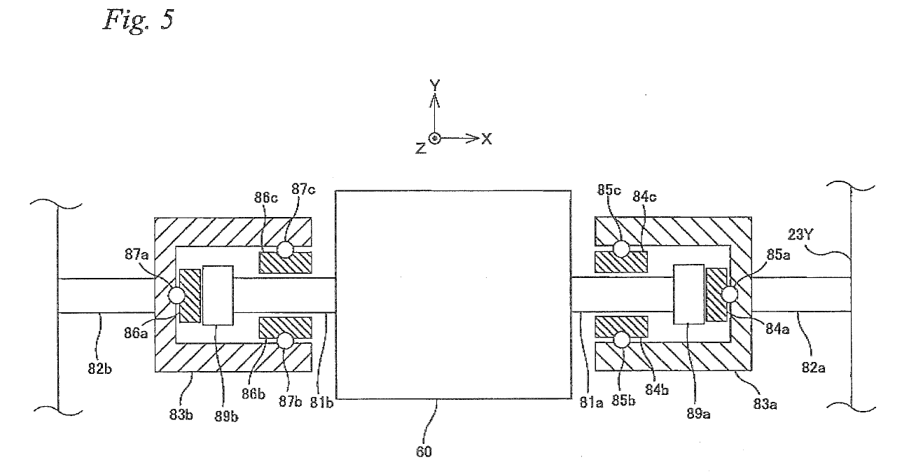

Next, a coupling structure between empty-weight cancelling device 60 and Y coarse movement stage 23Y, which is used to move empty-weight cancelling device 60 and Y coarse movement stage 23Y in conjunction in the X-axis direction and the Y-axis direction, is described. FIG. 5 shows the coupling structure between empty-weight cancelling device 60 and Y coarse movement stage 23Y.

As shown in FIG. 3, empty-weight cancelling device 60 has a pair of coupling members 81a and 81b extending in the +X direction and the −X direction respectively, outside the peripheral wall of housing 61 below the pair of X arms 64X described earlier. At the tips of coupling members 81a and 81b, pressed members 89a and 89b that each have a surface parallel to a YZ plane are fixed, respectively, as shown in FIG. 5. And, on the opposed surfaces (the surface on the +X side and the surface on the −X side) that are opposed to each other, of the inner wall surfaces that define opening section 23Ya of Y coarse movement stage 23Y, a pair of coupling members 82a and 82b extending in the −X direction and the +X direction are fixed, respectively. As shown in FIG. 5, at the tips of coupling members 82a and 82b, support members 83a and 83b that are each formed so as to have a U-like XY sectional shape and are respectively opened in the −X direction and the +X direction are fixed, respectively. On the inner wall surface of support member 83a, air bearings 84a, 84b and 84c are attached via ball joints 85a, 85b and 85c respectively. The bearing surface of air bearing 84a is orthogonal to the X-axis direction and is opposed to pressed member 89a via a predetermined clearance. Further, the bearing surfaces of air bearings 84b and 84c are orthogonal to the Y-axis and are opposed to the side surface on the −Y side and the side surface on the +Y side of coupling member 81a, respectively, via a predetermined clearance. On the inner wall surface of support member 83b as well, air bearings 86a, 86b and 86c are attached via ball joints 87a, 87b and 87c respectively in a similar manner.

Air bearings 84a and 86a blow out a high-pressure gas supplied from a gas supplying device that is not illustrated, for example, air to pressed members 89a and 89b respectively, air bearings 84b and 86b blow out the gas to the side surfaces on the −Y side of coupling members 81a and 81b respectively, and air bearings 84c and 86c blow out the gas to the side surfaces on the +Y side of coupling members 81a and 81b respectively. When Y coarse movement stage 23Y moves in the +Y direction (or the −Y direction) on X coarse movement stage 23X, empty-weight cancelling device 60 is pressed by Y coarse movement stage 23Y in a noncontact state, owing to the static pressure of the gas blown out to between air bearing 84b (or 84c) and coupling member 81a and the static pressure of the gas blown out to between air bearing 86b (or 86c) and coupling member 81b, and accordingly empty-weight cancelling device 60 moves in the +Y direction (or the −Y direction) integrally with Y coarse movement stage 23Y. Further, when Y coarse movement stage 23Y moves in the −X direction (or the +X direction) because X coarse movement stage 23X moves in the X-axis direction on base frames 14, empty-weight cancelling device 60 is pressed by Y coarse movement stage 23Y in a noncontact state, owing to the static pressure of the gas blown out to between air bearing 84a and pressed member 89a (or air bearing 86a and pressed member 89b) and accordingly empty-weight cancelling device 60 moves in the −X direction (or the −+X direction) integrally with Y coarse movement stage 23Y and X coarse movement stage 23X.

As described above, while movement in the Z-axis direction of empty-weight cancelling device 60 is not restricted with respect to Y coarse movement stage 23Y, empty-weight cancelling device 60 moves in the X-axis direction and the Y-axis direction integrally with Y coarse movement stage 23Y, by being pressed by a plurality of air bearings 84a to 84c and 86a to 86c. And, the plurality of air bearings 84a to 84c and 86a to 86c are placed such that the pressing forces used when pressing empty-weight cancelling device 60 act on coupling members 81a and 82a and pressed members 89a and 89b within a plane parallel to the XY plane that includes a gravity center position CG2 (see FIG. 3) of empty-weight cancelling device 60 in the Z-axis direction. Accordingly, Y coarse movement stage 23Y can drive (drive at the gravity center) empty-weight cancelling device 60 along the XY plane that includes gravity center position CG2 of empty-weight cancelling device 60, and can restrain the moment around the X-axis or the Y-axis (in the θx or θy direction) from acting on empty-weight cancelling device 60. Incidentally, the respective air bearings can be placed at a plurality of positions in the Z-axis direction (so as to overlap in the depth direction of the page surface of FIG. 5). In such a case as well, by placing a plurality of air bearings in vertical symmetry with respect to the XY plane that includes gravity center position CG2, the empty-weight cancelling device can be driven at the gravity center. Incidentally, in the embodiment, the air bearings are installed on the Y coarse movement stage side, the installation side is not limited thereto as far as a gas membrane having stiffness can be formed between empty-weight cancelling device 60 and Y coarse movement stage 23Y, and for example, the air bearings can be installed on the empty-weight cancelling device side.

Next, a configuration of Y beam 70 that supports empty-weight cancelling device 60 is described. As can be seen from FIGS. 3 and 4, Y beam 70 is made up of an elongated hollow member having a prismatic columnar shape whose longitudinal direction is in the Y-axis direction, and is placed in opening section 23Xa of X coarse movement stage 23X, and one end and the other end of Y beam 70 in the longitudinal direction are supported from below by the pair of X guides 12, respectively. The size of Y beam 70 in the longitudinal direction (Y-axis direction) is set to a length that can cover a movement range of empty-weight cancelling device 60 in the Y-axis direction. On the lower surface of the end on the +Y side of Y beam 70, a tabular attachment member 71 (see FIG. 3) whose size in the X-axis direction is longer than that of Y beam 70 is fixed, and on the lower surface of attachment member 71, a pair of air bearings 73a are attached at a predetermined distance in the X-axis direction via ball joints 74a. The bearing surfaces of the pair of air bearings 73a are respectively opposed to the upper surface of X guide 12 on the +Y side.

Further, on the lower surface of the end on the −Y side of Y beam 70, as shown in FIG. 4, an attachment member 72 formed so as to have an inverse U-like sectional shape is fixed, and on the inner wall surface of attachment member 72, an air bearing 73b whose bearing surface is opposed to the upper surface of X guide 12 on the −Y side, and a pair of air bearings 73c and 73d whose bearing surfaces are Opposed to the side surface on the +Y side and the side surface on the −Y side of X guide 12 on the −Y side are attached via ball joints 74b, 74c and 74d, respectively. Incidentally, although the illustration is omitted in FIG. 4, air bearings 73b to 73d are also placed in pair at a predetermined distance in the X-axis direction, in a similar manner to the placement of air bearings 73a.

Each of air bearings 73a and 73b blows out a high-pressure gas (e.g. air) supplied from a gas supplying device that is not illustrated, to the upper surface (the guide surface) of X guides 12. Y beam 70 is supported by levitation in a noncontact manner above the pair of X guides 12, by the static pressure of the gas blown out from air bearings 73a and 73b. Further, air bearings 73a and 73b respectively blow out a high-pressure gas (e.g. air) supplied from a gas supplying device that is not illustrated, to the surfaces on both sides of X guide 12 on the −Y side, and restricts relative movement of Y beam 70 in the Y-axis direction with respect to X guide 12 by the static pressure of the gas. Accordingly, Y beam 70 can move straight only in the X-axis direction above the pair of X guides 12. Incidentally, the placement of the air bearings to restrict the relative movement of the Y beam in the Y-axis direction with respect to the X guides is not limited to the above-described placement, but for example, a pair of air bearings can be placed such that their bearing surfaces are respectively opposed to the inner side surfaces of a pair of the X guides that are opposed to each other (or to the outer side surfaces of the pair of the X guides).

On the upper surface of Y beam 70, as can be seen from FIGS. 3 and 4, a pair of Y guides 75 with the Y-axis direction serving as their longitudinal directions that are placed at a predetermined distance in the X-axis direction are fixed. At four corner portions on the lower surface of housing 61 of empty-weight cancelling device 60 described previously, a slide section 68 having an inverse U-like sectional shape is fixed that includes a plurality of rolling bearings (e.g. balls, skids or the like) and mechanically engage with Y guide 75 in a slidable state with respect to Y guide 75. Accordingly, while empty-weight cancelling device 60 is movable freely in the Y axis direction on Y beam 70, relative movement of empty-weight cancelling device 60 with respect to Y beam 70 is restricted in the X-axis direction. Because empty-weight cancelling device 60 does not move in the X-axis direction on Y beam 70, the width (the size in the X-axis direction) of the upper surface of Y beam 70 is set to roughly the same as the size of empty-weight cancelling device 60 in the X-axis direction, or more specifically, set to the requisite minimum size.

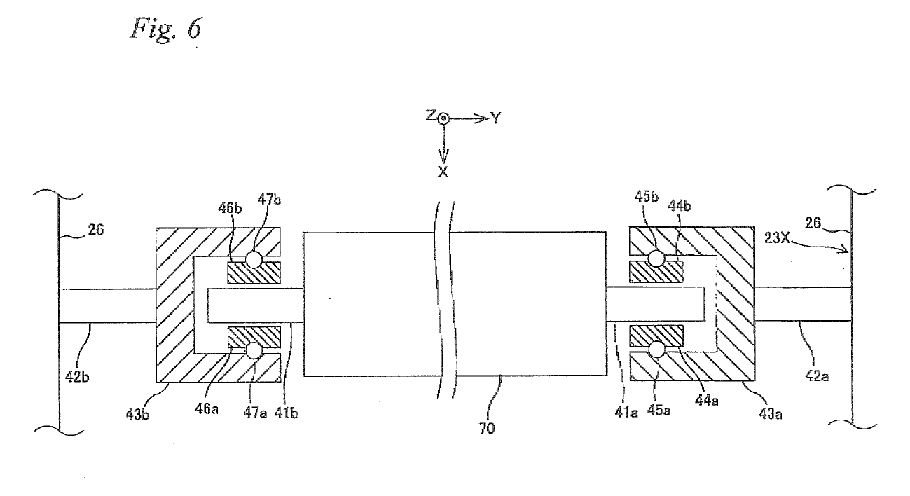

Further, X coarse movement stage 23X and Y beam 70 are coupled such that Y beam 70 moves integrally with empty-weight cancelling device 60 in the X-axis direction when empty-weight cancelling device 60 is driven in the X-axis direction by X coarse movement stage 23X. In the description below, a coupling structure between X coarse movement stage 23X and Y beam 70 is described. FIG. 6 shows the coupling structure between X coarse movement stage 23X and Y beam 70.

As shown in FIGS. 4 and 6, Y beam 70 has a pair of coupling members 41a and 41b extending in the +Y direction and the −Y direction at the end on the +Y side and the end on the −Y side, respectively. Further, as shown in FIG. 4, X coarse movement stage 23X has a pair of coupling members 42a and 42b respectively extending in the −Y direction and the +Y direction on a pair of opposed surfaces that are opposed to each other of the pair of connecting members 26. As shown in FIG. 6, at the tips of coupling members 42a and 42b, support members 43a and 43b are respectively fixed that are each formed to have a U-like XY sectional shape and are respectively opened in the −Y direction and the +Y direction. On a pair of opposed surfaces that are opposed to each other of the inner wall surface of support member 43a, air bearings 44a and 44b whose bearing surfaces are opposed to each other are attached via ball joints 45a and 45b. Also on the inner wall surface of support member 43b, similarly, air bearings 46a and 46b are attached via ball joints 47a and 47b. The bearing surface of each of air bearings 44a, 44b, 46a and 46b is orthogonal to a direction parallel to the X-axis direction.

Air bearings 44a and 46a respectively blow out a high-pressure gas (e,g. air) supplied from a gas supplying device that is not illustrated to the side surfaces on the +X side of coupling members 41a and 41b, and air bearings 44b and 46b respectively blow out the gas to the side surfaces on the −X side of coupling members 41a and 41b. When X coarse movement stage 23X moves in the −X direction (or the +X direction) on base frames 14, Y beam 70 is pressed in a noncontact mariner by X coarse movement stage 23X (see FIG. 4) owing to the static pressure of the gas blown out to between air bearing 44a (or 44b) and coupling member 41a and to between air bearing 46a (or 46b) and coupling member 41b, and accordingly Y beam 70 moves in the −X direction (or the +X direction) integrally with X coarse movement stage 23X.

As described above, while movement in the Z-axis direction of Y beam 70 is not restricted with respect to X coarse movement stage 23X, Y beam 70 moves in the X-axis direction integrally with X coarse movement stage 23X by being pressed by X coarse movement stage 23X via the gas blown out from a plurality of air bearings 44a, 44b, 46a and 46b. And, the plurality of air bearings 44a, 44b, 46a and 46b (see FIG. 6) are placed such that the pressing forces used when pressing Y beam 70 act on coupling members 41a and 41b within a plane parallel to the XY plane that includes a gravity center position CG3 of Y beam 70 in the Z-axis direction (to be more specific, the centers of the bearing surfaces are placed on a plane parallel to the XY plane that includes gravity center position CG3), as shown in FIG. 4. Accordingly, X coarse movement stage 23X can drive (drive at the gravity center) Y beam 70 along the XY plane that includes gravity center position CG3, and can restrain the moment around the Y-axis (in the θy direction) from acting on Y beam 70. Incidentally, the respective air bearings can be placed at a plurality of positions in the Z-axis direction (so as to overlap in the depth direction of the page surface of FIG. 6). In such a case as well, the Y beam can be drive at the gravity center by placing a plurality of air bearings in vertical symmetry with respect to the XY plane that includes gravity center position CG3.

In liquid crystal exposure apparatus 10 configured as described above, under control of the main controller that is not illustrated, mask M is loaded onto mask stage MST by a mask loader that is not illustrated and substrate P is loaded onto substrate holder PH on fine movement stage 21 by a substrate loader that is not illustrated. After that, the main controller executes alignment measurement using an alignment detection system that is not illustrated, and after the alignment measurement is completed, an exposure operation by a step-and-scan method is performed. Since this exposure operation is similar to the step-and-scan method that has conventionally been performed, the description thereabout is omitted.

As described above, in substrate stage device PST that liquid crystal exposure apparatus 10 of the embodiment has, when X coarse movement stage 23X moves in the X-axis direction, Y coarse movement stage 23Y, empty-weight cancelling device 60 and Y beam 70 move in the X-axis direction integrally with X coarse movement stage 23X, and when Y coarse movement stage 23Y moves in the Y-axis direction on X coarse movement stage 23X, empty-weight cancelling device 60 moves in the Y-axis direction integrally with Y coarse movement stage 23Y on Y beam 70. Since Y beam 70 is a stringer-like member arranged extending in the Y-axis direction and the upper surface of Y beam 70 covers the movement range of empty-weight cancelling device 60 in the Y-axis direction, empty-weight cancelling device 60 is constantly supported by Y beam 70 regardless of its position. Accordingly, fine movement stage 21 (i.e. substrate P) can be guided along the XY plane with high precision, without providing a member (e.g. a surface plate or the like) that has a guide surface large enough to cover the entire movement range of empty-weight cancelling device 60 in the X-axis and Y-axis directions.

Further, since X guides 12 are made up of a pair of columnar (bar-like) members each having a size in the width direction and a size in the height direction that are shorter than a size in the longitudinal direction, the materials (e.g. stone materials) can be secured without difficulty, and also the machining and the carriage can be performed without difficulty. Further, since the width size of Y beam 70 is set to around the same as the outer size of empty-weight cancelling device 60, the weight of liquid crystal exposure apparatus 10 can be reduced, compared with the case where a surface plate or the like that can cover the movement range of empty-weight cancelling device 60 is provided.

Further, since empty-weight cancelling device 60 and Y coarse movement stage 23Y are coupled in a noncontact manner, the vibration (disturbance) can be restrained from being transmitted from the outside to empty-weight cancelling device 60 via Y coarse movement stage 23Y. Further, since Y beam 70 and X coarse movement stage 23X are coupled in a noncontact manner, the vibration (disturbance) can be restrained from being transmitted from the outside to empty-weight cancelling device 60 via X coarse movement stage 23X and Y beam 70. Further, since Y beam 70 is levitated above X guides 12, the vibration can be restrained from being transmitted from the outside to a system composed of Y beam 70 and empty-weight cancelling device 60 via substrate stage mountings 33 and the like.

Incidentally, while the both ends of Y beam 70 in the longitudinal direction are supported by the pair of X guides 12 in the embodiment above, an intermediate portion (which may be at a plurality of positions) in the longitudinal direction of Y beam 70, for example, can also be supported by a member similar to the X guide, along with the support of the both ends (i.e., three or more of the members corresponding to the X-guide can be arranged). In this case, a member (e.g. a tabular member) having a lower stiffness than the Y beam of the embodiment can be used in place of the Y beam.

Further, the empty-weight cancelling device can be supported in a noncontact manner above the Y beam via an air bearing and the like. In this case, since the vibration is restrained from being transmitted to the empty-weight cancelling device via the Y beam, the Y beam can be supported on the X guides in a contact manner via rolling bearings and the like. Further, a configuration can be employed in which the empty-weight cancelling device is supported above the Y beam in a noncontact manner and also the Y beam is supported above the X guides in a noncontact manner similar to the embodiment above. Further, in the embodiment above, the Y beam is supported by levitation above the X guides via a predetermined clearance owing to the stiffness of the gas membrane formed by the high-pressure gas blown out from the air bearings, but this is not intended to be limiting, and the Y beam can be levitated above the X guides, for example, in a magnetic method.

Further, the coupling structure used to integrally move empty-weight cancelling device 60 and Y coarse movement stage 23Y and the coupling structure used to integrally move Y beam 70 and X coarse movement stage 23X are not limited to those described above in the embodiment above, but can appropriately be changed. For example, by using a coupling structure in which a thrust is transmitted only in one axial direction like the coupling structure between Y beam 70 and X coarse movement stage 23X, the +X side, the −X side, the +Y side and the −Y side of the empty-weight cancelling device and the Y coarse movement stage can be coupled. Further, by using a coupling structure in which a thrust is transmitted in two axial directions like the coupling structure between empty-weight cancelling device 60 and Y coarse movement stage 23Y, Y beam 70 and X coarse movement stage 23X can be coupled (in the embodiment above, air bearings 73c and 73d that restrict the movement of the Y beam in the Y-axis direction become unnecessary). Besides, the number, the placement and the like of the air bearings can appropriately be changed, and the point is that between empty-weight cancelling device 60 and Y coarse movement stage 23Y, the thrust should be transmitted, in a noncontact manner, in the orthogonal two axial directions which are the X-axis direction and the Y-axis direction, and between Y beam 70 and X coarse movement stage 23X, the thrust should be transmitted in a noncontact manner in the X-axis direction while the position of Y beam 70 in the Y--axis direction is restricted in a noncontact manner.

Further, in the embodiment above, X beam 70 and X coarse movement stage 23X, and empty-weight cancelling device 60 and Y coarse movement stage 23Y are respectively coupled in a noncontact manner via a plurality of air bearings. In the embodiment above, however, the Y beam and the X coarse movement stage, and the empty-weight cancelling device and the Y coarse movement stage can be mechanically coupled, respectively, using a member like the flexure that is disclosed in, for example, PCT International Publication No. 2008/129762 the corresponding U.S. Patent Application Publication No. 2010/0018950) and the like.

Further, in the embodiment above, while the configuration is employed in which the relative movement of Y beam 70 in the X-axis direction is restricted by the air bearings that blow out the high-pressure gas to X guides 12, this is not intended to be limiting, and for example, a configuration can be employed in which the relative movement of Y beam 70 in the X-axis direction is restricted by the air bearings that blow out the high-pressure gas to the X coarse movement stage. Further, the shape of a member (which is the Y beam in the embodiment above) that supports the empty-weight cancelling device is not limited the shape (the stringer-like member) in the embodiment above, but can be another shape (e.g. a tabular shape).

Further, in the embodiment above, while the Y beam is configured to be driven by the X coarse movement stage, the drive method of the Y beam is not limited thereto as far as the Y coarse movement stage and the X coarse movement stage are configured to integrally move in the X-axis direction, and for example, an actuator for exclusive use (e.g. a linear motor or the like) can be used. Further, in the embodiment above, while the empty-weight cancelling device is configured to be driven by the Y coarse movement stage, the drive method of the empty-weight cancelling device is not limited thereto as far as the empty-weight cancelling device and the Y coarse movement stage are configured to integrally move along the XY plane, and for example, an actuator for exclusive use (e.g. a liner motor or the like) can be used.

Further, the illumination light can be ultraviolet light, such as ArF excimer laser light (with a wavelength of 193 nm) and KrF excimer laser light (with a wavelength of 248 nm), or vacuum ultraviolet light such as F₂ laser light (with a wavelength of 157 nm). Further, as the illumination light, for example, a harmonic wave, which is obtained by amplifying a single-wavelength laser light in the infrared or visible range emitted by a DFB semiconductor laser or fiber laser with a fiber amplifier doped with, for example, erbium (or both erbium and ytterbium), and by converting the wavelength into ultraviolet light using a nonlinear optical crystal, can also be used. Further, solid state laser (with a wavelength of 355 nm, 266 nm) or the like can also be used.

Further, in the embodiment above, while the case has been described where projection optical system PL is a projection optical system by a multi-lens method that is equipped with a plurality of projection optical units, the number of the projection optical units is not limited thereto, and there should be one or more projection optical units. Further, projection optical system PL is not limited to the projection optical system by a multi-lens method, but for example, can be a projection optical system that uses a large-size mirror of the Offner type.

Further, in the embodiment above, while the case has been described where the projection optical system whose projection magnification is an equal magnification is used as projection optical system PL, this is not intended to be limiting, and the projection optical system can be either of a reduction system or a magnifying system.

Further, in the embodiment above, a light transmissive type mask is used, which is obtained by forming a predetermined light-shielding pattern (or a phase pattern or a light-attenuation pattern) on a light transmissive mask substrate. Instead of this mask, however, as disclosed in, for example, U.S. Pat. No. 6,778,257, an electron mask (a variable shaped mask) on which a light-transmitting pattern, a reflection pattern, or an emission pattern is formed according to electronic data of the pattern that is to be exposed, for example, a variable shaped mask that uses a DMD (Digital Micromirror Device) that is a type of a non-emission type image display element (which is also called a spatial light modulator) can also be used.

Incidentally, it is especially effective to apply the exposure apparatus of the embodiment above to an exposure apparatus in which a substrate with a size (which includes at least one of an outer diameter, a diagonal line and a side) not less than 500 mm, for example, a large substrate for a flat-panel display (FPD), such as a liquid crystal display element, is exposed. This is because the exposure apparatus of the embodiment above has been configured so as to cope with the increase in size of substrates.

Incidentally, in the embodiment above, while the case has been described where the present invention is applied to a projection exposure apparatus that performs scanning type exposure that is accompanied by a step-and-scan operation of the plate, this is not intended to be limiting, and the exposure apparatus of the embodiment above can also be an exposure apparatus by a proximity method that does not use any projection optical systems. Further, the exposure apparatus of the embodiment above can also be an exposure apparatus by a step-and-repeat method (a so-called stepper) or an exposure apparatus by a step-and-stitch method, or the like.

Further, the use of the exposure apparatus is not limited to the exposure apparatus for liquid crystal display elements in which a liquid crystal display element pattern is transferred onto a rectangular glass plate, but the present invention can also be widely applied, for example, to an exposure apparatus for manufacturing semiconductors, and an exposure apparatus for producing thin-film magnetic heads, micromachines, DNA chips, and the like. Further, the present invention can be applied not only to an exposure apparatus for producing microdevices such as semiconductor devices, but can also be applied to an exposure apparatus in which a circuit pattern is transferred onto a glass substrate, a silicon wafer or the like to produce a mask or a reticle used in a light exposure apparatus, an EUV exposure apparatus, an X-ray exposure apparatus, an electron-beam exposure apparatus, and the like. Incidentally, an object that is subject to exposure is not limited to a glass plate, but for example, can be another object such as a wafer, a ceramic substrate, a film member, or a mask blank. Further, the present invention can also be applied to an exposure apparatus such as a liquid immersion type exposure apparatus in which a space between a projection optical system and a wafer is filled with a liquid, which is disclosed in, for example, U.S. Patent Application Publication No. 2005/0259234 and the like, as an exposure apparatus to transfer a circuit pattern onto a silicon wafer or the like.

Further, as disclosed in, for example, POT International Publication No. 2001/035168, the present invention can also be applied to an exposure apparatus (a lithography system) in which line-and-space patterns are formed on a wafer by forming interference fringes on the wafer.

Incidentally, the present invention can be applied not only to the exposure apparatus but also to, for example, an element manufacturing apparatus equipped with a functional liquid deposition device by an ink-jet method.

Incidentally, the above disclosures of all the publications, the PCT International Publications, and the U.S. Patent Application Publications, and the U.S. patents that are cited in the description above and related to exposure apparatuses and the like are each incorporated herein by reference.

Device Manufacturing Method

A manufacturing method of a microdevice that uses exposure apparatus 10 of the embodiment above in a lithography process is described next. In exposure apparatus 10 of the embodiment above, a liquid crystal display element as a microdevice can be obtained by forming a predetermined pattern (such as a circuit pattern or an electrode pattern) on a plate (a glass substrate).

Pattern Forming Process

First of all, a so-called optical lithography process in which a pattern image is formed on a photosensitive substrate (such as a glass substrate coated with a resist) is executed using exposure apparatus 10 described above. In this optical lithography process, a predetermined pattern that includes many electrodes and the like is formed on the photosensitive substrate. After that, the exposed substrate undergoes the respective processes such as a development process, an etching process and a resist removing process, and thereby the predetermined pattern is formed on the substrate.

Color Filter Forming Process

Next, a color filter in which many sets of three dots corresponding to R (Red), G (Green) and B (blue) are disposed in a matrix shape, or a color filter in which a plurality of sets of filters of three stripes of R, G and B are disposed in horizontal scanning line directions is formed.

Cell Assembling Process

Next, a liquid crystal panel (a liquid crystal cell) is assembled using the substrate having the predetermined pattern obtained in the pattern forming process, the color filter obtained in the color filter forming process, and the like. For example, a liquid crystal panel (a liquid crystal cell) is manufactured by injecting liquid crystal between the substrate having the predetermined pattern obtained in the pattern forming process and the color filter obtained in the color filter forming process.

Module Assembling Process

After that, a liquid crystal display element is completed by attaching respective components such as an electric circuit that causes a display operation of the assembled liquid crystal panel (liquid crystal cell) to be performed, and a backlight.

In this case, since exposure of the plate is performed with high throughput and high precision using the exposure apparatus of the embodiment above in the pattern forming process, the productivity of liquid crystal display elements can be improved as a consequence.

While the above-described embodiment of the present invention is the presently preferred embodiment thereof, those skilled in the art of lithography systems will readily recognize that numerous additions, modifications, and substitutions may be made to the above-described embodiment without departing from the spirit and scope thereof. It is intended that all such modifications, additions, and substitutions fall within the scope of the present invention, which is best defined by the claims appended below.

What is claimed is:

1. A movable body apparatus, comprising:
a first movable body that is movable along a two-dimensional plane that includes a first axis and a second axis orthogonal to each other;
an empty-weight supporting member that supports an empty weight of the first movable body, and moves along a plane parallel to the two-dimensional plane integrally with the first movable body within a predetermined range; and
a movable support member arranged extending in a direction parallel to the first axis at least within the predetermined range, which supports the empty-weight supporting member and moves integrally with the empty-weight supporting member in a direction parallel to the second axis.

2. The movable body apparatus according to claim 1, further comprising:
a second movable body that supports the first movable body, and drives the first movable body in the direction parallel to the first axis by moving integrally with the empty-weight supporting member in the direction parallel to the first axis within the predetermined plane.

3. The movable body apparatus according to claim 2, further comprising:
a third movable body that supports the second movable body, and drives the first and second movable bodies and the empty-weight supporting member in the direction parallel to the second axis by moving integrally with the movable support member in the direction parallel to the second axis within the predetermined plane.

4. The movable body apparatus according to claim 3, further comprising:
a plurality of fixed support members with the direction parallel to the second axis serving as their longitudinal directions, which are placed at a predetermined distance in the direction parallel to the first axis, wherein
the movable support member is made up of a member with the direction parallel to the first axis serving as its longitudinal direction, and sections of the movable support member that are different from each other in the longitudinal direction are respectively supported by the plurality of fixed support members.

5. The movable body apparatus according to claim 4, wherein
the third movable body and the fixed support members are separate in terms of vibration.

6. The movable body apparatus according to claim 4, wherein
the fixed support members have guide surfaces parallel to the two-dimensional plane, and
the movable support member is supported above the guide surfaces in a noncontact manner.

7. The movable body apparatus according to claim 4, wherein
the movable support member has a pair of first static gas bearings whose bearing surfaces are orthogonal to the direction parallel to the first axis and face directions opposite to each other, and
the pair of first static gas bearings restrict, in a noncontact manner, relative movement of the movable support member with respect to the fixed support members in the direction parallel to the first axis, by blowing out a gas to at least one of the plurality of fixed support members.

8. The movable body apparatus according to claim 3, wherein
the third movable body has an opening section that penetrates in a direction orthogonal to the two-dimensional plane, and
the movable support member is placed in the opening section.

9. The movable body apparatus according to claim 3, wherein
the movable support member is driven in the direction parallel to the second axis by the third movable body.

10. The movable body apparatus according to claim 9, wherein
the third movable body makes a drive force act on the movable support member within a plane parallel to the two-dimensional plane that includes a gravity center position of the movable support member.

11. The movable body apparatus according to claim 10, further comprising:
a second static gas bearing that blows out a gas to between the third movable body and the movable support member, wherein
the third movable body presses the movable support member in a noncontact manner via the gas blown out from the second static gas bearing, when the third movable body moves in the direction parallel to the second axis.

12. The movable body apparatus according to claim 11, wherein
the second static gas bearing has a bearing surface that is parallel to a plane orthogonal to the second axis, and at least one of the second static gas bearing is placed on one side and the other side, respectively, in the direction parallel to the first axis with respect to the third movable body.

13. The movable body apparatus according to claim 2, wherein
the empty-weight supporting member is driven along a plane parallel to the two-dimensional plane by the second movable body.

14. The movable body apparatus according to claim 13, wherein
the second movable body makes a drive force act on the empty-weight supporting member within a plane parallel to the two-dimensional plane that includes a gravity center position of the empty-weight supporting member.

15. The movable body apparatus according to claim 13, further comprising:
a third static gas bearing that blows out a gas to between the second movable body and the empty-weight supporting member, wherein
the second movable body presses the empty-weight supporting member in a noncontact manner via the gas blown out from the third static gas bearing, when the second movable body moves along a plane parallel to the two-dimensional plane.

16. The movable body apparatus according to claim 15, wherein
the third static gas bearing includes a plurality of second-axis-direction-drive bearings whose bearing surfaces are parallel to a plane orthogonal to the first axis and a plurality of first-axis-direction-drive bearings whose bearing surfaces are parallel to a plane orthogonal to the second axis,
at least one of the plurality of second-axis-direction-drive bearings is placed on one side and the other side, respectively, in the direction parallel to the second axis with respect to the empty-weight supporting member, and
at least one of the plurality of first-axis-direction-drive bearings is placed on one side and the other side, respectively, in the direction parallel to the first axis with respect to the empty-weight supporting member.

17. The movable body apparatus according to claim 1, further comprising:
a restriction member that restricts movement of the movable support member in the direction parallel to the first axis.

18. The movable body apparatus according to claim 1, wherein
the movable support member has a support surface parallel to the two-dimensional plane that supports the empty-weight supporting member, and
the support surface and the empty-weight supporting member have roughly the same size in the direction parallel to the second axis.

19. The movable body apparatus according to claim 1, wherein
the empty-weight supporting member supports the first movable body in a noncontact manner.

20. An exposure apparatus to expose an object by irradiating the object with an energy beam, the apparatus comprising:
the movable body apparatus according to claim 1 in which the object is held by the first movable body; and
a patterning device that irradiates the object mounted on the first movable body with the energy beam.

21. The exposure apparatus according to claim 20, wherein
the object is a substrate that is used for a display panel of a display device.

22. A device manufacturing method, comprising:
exposing an object using the exposure apparatus according to claim 20; and
developing the object that has been exposed.

23. A movable body apparatus, comprising:
a first movable body that is movable along a two-dimensional plane that includes a first axis and a second axis orthogonal to each other;
a second movable body that supports the first movable body, and drives the first movable body along a plane parallel to the two-dimensional plane by moving along a plane parallel to the two-dimensional plane within a predetermined range;
an empty-weight supporting member that supports an empty weight of the first movable body, and moves along a plane parallel to the two-dimensional plane integrally with the second movable body; and
a static gas bearing that blows out a gas to between the second movable body and the empty-weight supporting member, wherein
the second movable body presses the empty-weight supporting member in a noncontact manner via the gas blown out from the static gas bearing when the second movable body moves along the plane parallel to the two-dimensional plane.

24. The movable body apparatus according to claim 23, wherein
the second movable body makes a pressing force act on the empty-weight supporting member within a plane parallel to the two-dimensional plane that includes a gravity center position of the empty-weight supporting member.

25. The movable body apparatus according to claim 23, wherein
the static gas bearing includes a plurality of second-axis-direction-drive bearings whose bearing surfaces are parallel to a plane orthogonal to the first axis and a plurality of first-axis-direction-drive bearings whose bearing surfaces are parallel to a plane orthogonal to the second axis,
at least one of the plurality of second-axis-direction-drive bearings is placed on one side and the other side, respectively, in the direction parallel to the second axis with respect to the empty-weight supporting member, and
at least one of the plurality of first-axis-direction-drive bearings is placed on one side and the other side, respectively, in the direction parallel to the first axis with respect to the empty-weight supporting member.

26. The movable body apparatus according to claim 23, wherein
the empty-weight supporting member supports the first movable body in a noncontact manner.

27. An exposure apparatus to expose an object by irradiating the object with an energy beam, the apparatus comprising:
the movable body apparatus according to claim 23 in which the object is held by the first movable body; and
a patterning device that irradiates the object mounted on the first movable body with the energy beam.

28. The exposure apparatus according to claim 27, wherein
the object is a substrate that is used for a display panel of a display device.

29. A device manufacturing method, comprising:
exposing an object using the exposure apparatus according to claim 27; and
developing the object that has been exposed.

30. An exposure method of exposing an object by irradiating the object with an energy beam, the method comprising:
driving a first movable body that holds the object, along a two-dimensional plane that includes a first axis and a second axis orthogonal to each other, within a predetermined range in the two-dimensional plane;
causing an empty-weight supporting member to move along a plane parallel to the two-dimensional plane integrally with the first movable body, the empty-weight supporting member supporting an empty weight of the first movable body;
driving a movable support member integrally with the empty-weight supporting member in a direction parallel to the second axis, the movable support member being arranged extending in a direction parallel to the first axis at least within the predetermined range and supporting the empty-weight supporting member; and
irradiating the object with the energy beam.

31. The exposure method according to claim 30, wherein
in the driving the first movable body, the first movable body is driven in the direction parallel to the first axis using a second movable body that is movable in the direction parallel to the first axis.

32. The exposure method according to claim 31, further comprising:
driving the first and second movable bodies in the direction parallel to the second axis within the predetermined range, using a third movable body that is movable in the direction parallel to the second axis.

33. The exposure method according to claim 30, wherein
the movable support member is a member with the direction parallel to the first axis serving as its longitudinal direction, and
in the driving the movable support member, the movable support member is driven in a state where sections of the movable support member that are different from each other in the longitudinal direction are supported on a plurality of fixed support members with the direction parallel to the second axis serving as their longitudinal directions that are placed at a predetermined distance in the direction parallel to the first axis.

34. The exposure method according to claim 33, wherein
in the driving the movable support member, relative movement of the movable support member with respect to the fixed support members in the direction parallel to the first axis is restricted in a noncontact manner, by causing a pair of first static gas bearings to blow out a gas to at least one of the plurality of fixed support members, the pair of first static gas bearings being arranged at the movable support member and having bearing surfaces that are orthogonal to the direction parallel to the first axis and face directions opposite to each other.

35. The exposure method according to claim 30, wherein
in the driving the movable support member, movement of the movable support member in the direction parallel to the first axis is restricted.

36. The exposure method according to claim 30, wherein
in the driving the movable support member, the movable support member is driven in the direction parallel to the second axis by the third movable body.

37. The exposure method according to claim 36, wherein
the third movable body makes a drive force act on the movable support member within a plane parallel to the two-dimensional plane that includes a gravity center position of the movable support member.

38. The exposure method according to claim 36, wherein
the third movable body presses the movable support member in a noncontact manner via a gas blown out from a second static gas bearing to between the third movable body and the movable support member, when the third movable body moves in the direction parallel to the second axis.

39. The exposure method according to claim 30, wherein
in the causing the empty-weight supporting member to move, the empty-weight supporting member is driven along a plane parallel to the two-dimensional plane by the second movable body.

40. The exposure method according to claim 39, wherein
the second movable body makes a drive force act on the empty-weight supporting member within a plane parallel to the two-dimensional plane that includes a gravity center position of the empty-weight supporting member.

41. The exposure method according to claim 39, wherein
the second movable body presses the empty-weight supporting member in a noncontact manner via a gas blown out from a third static gas bearing to between the second movable body and the empty-weight supporting member, when the second movable body moves along a plane parallel to the two-dimensional plane.

42. A device manufacturing method, comprising:
exposing an object using the exposure method according to claim 30; and
developing the object that has been exposed.

43. An exposure method of exposing an object by irradiating the object with an energy beam, the method comprising:
driving a first movable body that holds the object along a plane parallel to a predetermined two-dimensional plane using a second movable body that is movable along a plane parallel to the two-dimensional plane;
causing an empty-weight supporting member that supports an empty weight of the first movable body to move along a plane parallel to the two-dimensional plane integrally with the second movable body;
causing the second movable body to press the empty-weight supporting member in a noncontact manner via a gas blown out from a static gas bearing to between the second movable body and the empty-weight supporting member, when the second movable body moves along the plane parallel to the two-dimensional plane; and
irradiating the object with the energy beam.

44. The exposure method according to claim 43, wherein
in the causing the second movable body to press the empty-weight supporting member, the second movable body makes a pressing force act on the empty-weight supporting member within a plane parallel to the two-dimensional plane that includes a gravity center position of the empty-weight supporting member.

45. A device manufacturing method, comprising:
exposing an object using the exposure method according to claim 43; and
developing the object that has been exposed.

46. An exposure apparatus to expose an object by irradiating the object with an energy beam, the apparatus comprising:
a first stage that is movable along a two-dimensional plane that includes a first axis and a second axis orthogonal to each other, while holding the object;
an empty-weight supporting member that supports an empty weight of the first stage, and moves along a plane parallel to the two-dimensional plane integrally with the first stage within a predetermined range;
a movable support member arranged extending in a direction parallel to the first axis at least within the predetermined range, which supports the empty-weight supporting member and moves integrally with the empty-weight supporting member in a direction parallel to the second axis; and
a patterning device that irradiates the object held by the first stage with the energy beam.

47. The exposure apparatus according to claim 46, further comprising:
a second stage that supports the first stage, and drives the first stage in the direction parallel to the first axis by moving integrally with the empty-weight supporting member in the direction parallel to the first axis within the predetermined range.

48. The exposure apparatus according to claim 47, further comprising:
a third stage that supports the second stage, and drives the first and second stages and the empty-weight supporting member in the direction parallel to the second axis by moving integrally with the movable support member in the direction parallel to the second axis within the predetermined range.

49. The exposure apparatus according to claim 48, further comprising:
a plurality of guide members with the direction parallel to the second axis serving as their longitudinal directions, which are placed at a predetermined distance in the direction parallel to the first axis, wherein
the movable support member is made up of a member with the direction parallel to the first axis serving as its longitudinal direction, and sections of the movable support member that are different from each other in the longitudinal direction are respectively supported by the plurality of guide members.

50. The exposure apparatus according to claim 49, wherein
the third stage and the guide members are separate in terms of vibration.

51. The exposure apparatus according to claim 49, wherein
the guide members have guide surfaces parallel to the two-dimensional plane, and
the movable support member is supported above the guide surfaces in a noncontact manner.

52. The exposure apparatus according to claim 49, wherein
the movable support member has a pair of first static gas bearings whose bearing surfaces are orthogonal to the direction parallel to the first axis and face directions opposite to each other, and
the pair of first static gas bearings restrict, in a noncontact manner, relative movement of the movable support member with respect to the guide members in the direction parallel to the first axis, by blowing out a gas to at least one of the plurality of guide members.

53. The exposure apparatus according to claim 48, wherein
the third stage has an opening section that penetrates in a direction orthogonal to the two-dimensional plane, and
the movable support member is placed in the opening section.

54. The exposure apparatus according to claim 48, wherein
the movable support member is driven in the direction parallel to the second axis by the third stage.

55. The exposure apparatus according to claim 54, wherein
the third stage makes a drive force act on the movable support member within a plane parallel to the two-dimensional plane that includes a gravity center position of the movable support member.

56. The exposure apparatus according to claim 55, further comprising:
a second static gas bearing that blows out a gas to between the third stage and the movable support member, wherein
the third stage presses the movable support member in a noncontact manner via the gas blown out from the second static gas bearing, when the third stage moves in the direction parallel to the second axis.

57. The exposure apparatus according to claim 56, wherein
the second static gas bearing has a bearing surface that is parallel to a plane orthogonal to the second, axis, and at least one of the second static gas bearing is placed on one side and the other side, respectively, in the direction parallel to the first axis with respect to the third stage.

58. The exposure apparatus according to claim 47, wherein
the empty-weight supporting member is driven along a plane parallel to the two-dimensional plane by the second stage.

59. The exposure apparatus according to claim 58, wherein
the second stage makes a drive force act on the empty-weight supporting member within a plane parallel to the two-dimensional plane that includes a gravity center position of the empty-weight supporting member.

60. The exposure apparatus according to claim 58, further comprising:
a third static gas bearing that blows out a gas to between the second stage and the empty-weight supporting member, wherein
the second stage presses the empty-weight supporting member in a noncontact manner via the gas blown out from the third static gas bearing, when the second stage moves along a plane parallel to the two-dimensional plane.

61. The exposure apparatus according to claim 60, wherein
the third static gas bearing includes a plurality of second-axis-direction-drive bearings whose bearing surfaces are parallel to a plane orthogonal to the first axis and a plurality of first-axis-direction-drive bearings whose bearing surfaces are parallel to a plane orthogonal to the second axis,
at least one of the plurality of second-axis-direction-drive bearings is placed on one side and the other side, respectively, in the direction parallel to the second axis with respect to the empty-weight supporting member, and
at least one of the plurality of first-axis-direction-drive bearings is placed on one side and the other side, respectively, in the direction parallel to the first axis direction with respect to the empty-weight supporting member.

62. The exposure apparatus according to claim 46, further comprising:
a restriction member that restricts movement of the movable support member in the direction parallel to the first axis.

63. The exposure apparatus according to claim 46, wherein
the movable support member has a support surface parallel to the two-dimensional plane that supports the empty-weight supporting member, and
the support surface and the empty-weight supporting member have roughly the same size in the direction parallel to the second axis.

64. The exposure apparatus according to claim 46, wherein
the empty-weight supporting member supports the first stage in a noncontact manner.

65. The exposure apparatus according to claim 46, wherein
the object is a substrate with a size not less than 500 mm.

66. A device manufacturing method, comprising:
exposing an object using the exposure apparatus according to claim 46; and
developing the object that has been exposed.

67. A flat-panel display manufacturing method, comprising:
exposing a substrate for a flat-panel display using the exposure apparatus according to claim 46; and
developing the substrate that has been exposed.

68. An exposure apparatus to expose an object by irradiating the object with an energy beam, the apparatus comprising:
a first stage that is movable along a two-dimensional plane that includes a first axis and a second axis orthogonal to each other, while holding the object;
a second stage that supports the first stage, and drives the first stage along a plane parallel to the two-dimensional plane by moving along a plane parallel to the two-dimensional plane within a predetermined range;
an empty-weight supporting member that supports an empty weight of the first stage, and moves along a plane parallel to the two-dimensional plane integrally with the second stage;
a static gas bearing that blows out a gas to between the second stage and the empty-weight supporting member; and
a patterning device that irradiates the object held by the first stage with the energy beam, wherein
the second stage presses the empty-weight supporting member in a noncontact manner via the gas blown out from the static gas bearing, when the second stage moves along the plane parallel to the two-dimensional plane.

69. The exposure apparatus according to claim 68, wherein
the second stage makes a pressing force act on the empty-weight supporting member within a plane parallel to the two-dimensional plane that includes a gravity center position of the empty-weight supporting member.

70. The exposure apparatus according to claim 68, wherein
the static gas bearing includes a plurality of second-axis-direction-drive bearings whose bearing surfaces are parallel to a plane orthogonal to the first axis and a plurality of first-axis-direction-drive bearings whose bearing surfaces are parallel to a plane orthogonal to the second axis,
at least one of the plurality of second-axis-direction-drive bearings is placed on one side and the other side, respectively, in the direction parallel to the second axis with respect to the empty-weight supporting member, and
at least one of the plurality of first-axis-direction-drive bearings is placed on one side and the other side, respectively, in the direction parallel to the first axis with respect to the empty-weight supporting member.

71. The exposure apparatus according to claim 68, wherein
the empty-weight supporting member supports the first stage in a noncontact manner.

72. The exposure apparatus according to claim 68, wherein
the object is a substrate with a size not less than 500 mm.

73. A device manufacturing method, comprising:
exposing an object using the exposure apparatus according to claim 68; and
developing the object that has been exposed.

74. A flat-panel display manufacturing method, comprising:
exposing a substrate for a flat-panel display using the exposure apparatus according to claim 68; and
developing the substrate that has been exposed.
